(19) United States
(12) Patent Application Publication
(10) Pub. No.: US 2022/0091063 A1
(43) Pub. Date: Mar. 24, 2022

(54) HETEROGENEOUS INTEGRATION OF PLURAL GRAPHENE SENSORS ON 3D COIN CMOS ELECTRONICS

(71) Applicant: KING ABDULLAH UNIVERSITY OF SCIENCE AND TECHNOLOGY, Thuwal (SA)

(72) Inventors: Muhammad Mustafa HUSSAIN, Hercules, CA (US); Sohail Faizan SHAIKH, Thuwal (SA)

(21) Appl. No.: 17/424,934

(22) PCT Filed: Feb. 12, 2020
(86) PCT No.: PCT/IB2020/051141

§ 371 Date: Jul. 22, 2021

Related U.S. Application Data
(60) Provisional application No. 62/811,724, filed on Feb. 28, 2019.

(51) Int. Cl. G01N 27/22; G01K 7/22; H01L 27/142; H01L 25/00

(52) U.S. Cl. CPC G01N 27/223; G01K 7/226; H01L 24/16; H01L 25/50; H01L 27/142

(57) ABSTRACT

A physically compliant, 3-dimensional, heterogeneously integrated system includes electronics that have a metal-oxide-semiconductor structure; plural graphene-based sensors; interconnects configured to electrically connect the electronics to the plural graphene-based sensors; and a first polymer layer that extends between the electronics and the plural graphene-based sensors so that the electronics are prevented from directly contacting the plural graphene-based sensors. The electronics, the plural graphene-based sensors, the interconnects, and the first polymer layer are configured to have a thickness that allow the entire system to bend to have a bending radius less than 10 mm.

### CROSS-REFERENCE TO RELATED APPLICATIONS

This application claims priority to U.S. Provisional Patent Application No. 62/811,724, filed on Feb. 28, 2019, entitled “HETEROGENEOUSLY INTEGRATED PHYSICALLY COMPLIANT 3D-IC CMOS ELECTRONIC SYSTEM,” the disclosure of which is incorporated herein by reference in its entirety.

### BACKGROUND

### Technical Field

Embodiments of the subject matter disclosed herein generally relate to a complementary metal-oxide-semiconductor (CMOS) compatible manufacturable heterogeneous, physically compliant, coin architecture 3D-CMOS electronics with plural graphene sensors.

### Discussion of the Background

Technological advances to augment the quality of life need Internet of Things (IoT) and Internet of Everything (IoE) seamlessly connecting device-data-people-process. An efficient IoT/IoE system needs a pragmatic approach to integrate millions of sensors on complex, asymmetrical, and challenging biological and non-living surfaces. Therefore, a robust integration strategy is required for achieving a reliable physically compliant electronic system. A larger effort is undergone in the emerging field of flexible electronics, exploring 0D/1D/2D materials, organic materials, polymers, and low-cost processing techniques to achieve the IoT/IoE system. Nonetheless, for data management, the conventional rigid integrated circuits (ICs) are still in use due to their superior performances. Therefore, different approaches have been explored to use self-assembled layers, thinned devices, microbumps and solders, specific expensive bonding polymeric layers, and high temperature processes based pressure application for stack bonding.

A variety of methods are used to reduce the CMOS devices into a thin and flexible form. Stacking ICs without substantial thickness reduction for through-silicon-via (TSV) restricts the efficient area utilization and yields a thicker stack, thereby losing the flexibility. In-plane single layer based assembly of active and passive electronics causes severe skin/cell inflammation due to the amount of heat dissipation of the active devices, in addition to covering a huge surface area.

To overcome these challenges, there is a need for a reliable heterogeneous 3D integration scheme to obtain a physically compliant standalone CMOS electronic system having the ability to interface (different material based, e.g., graphene) millions of sensors.

### BRIEF SUMMARY OF THE INVENTION

According to an embodiment, there is a physically compliant, 3-dimensional, heterogeneously integrated system that includes electronics that have a metal-oxide-semiconductor structure, plural graphene-based sensors, interconnects configured to electrically connect the electronics to the plural graphene-based sensors, and a first polymer layer that extends between the electronics and the plural graphene-based sensors so that the electronics are prevented from directly contacting the plural graphene-based sensors. The electronics, the plural graphene-based sensors, the interconnects, and the first polymer layer are configured to have a thickness that allow the entire system to bend to have a bending radius less than 10 mm.

According to another embodiment, there is a method for making a physically compliant, 3-dimensional, heterogeneously integrated system and the method includes a step of forming a first polymer layer over a temporary Si-based substrate, a step of depositing interconnects over a first face of the first polymer layer, a step of attaching electronics that have a metal-oxide-semiconductor structure to the interconnects, on the first face of the first polymer layer, a step of reducing a thickness of the electronics by a soft etch back process until the electronics become flexible and bend to have a bending radius of less than 10 mm; a step of encapsulating the thinned electronics using a soft polymer, a step of removing the temporary Si-based substrate to free a second face of the first polymer layer, and a step of transferring plural graphene-based sensors onto the second face of the first polymer layer. The first polymer layer extends between the electronics and the plural graphene-based sensors so that the electronics are prevented from directly contacting the plural graphene-based sensors.

According to yet another embodiment, there is a physically compliant, 3-dimensional, heterogeneously integrated system that includes electronics that have a metal-oxide-semiconductor structure; plural graphene-based sensors; interconnects configured to electrically connect the electronics to the plural graphene-based sensors; and a polymer layer that extends between the electronics and the plural graphene-based sensors so that the electronics are prevented from directly contacting the plural graphene-based sensors. There is no Si-based substrate, and the plural graphene-based sensors include more than a million graphene sensors.

### BRIEF DESCRIPTION OF THE DRAWINGS

For a more complete understanding of the present invention, reference is now made to the following descriptions taken in conjunction with the accompanying drawings, in which:

FIG. 1 is a flowchart of a method for making a physically compliant, 3-dimensional, heterogeneously integrated system;

FIGS. 2A to 2L illustrate various steps of forming the physically compliant, 3-dimensional, heterogeneously integrated system;

FIG. 3 illustrates the flexibility of the physically compliant, 3-dimensional, heterogeneously integrated system, when compared to a traditional integrated circuit;

FIG. 4 is a flowchart of another method for forming a physically compliant, 3-dimensional, heterogeneously integrated system;

FIGS. 5A to 5L illustrate various steps of forming the physically compliant, 3-dimensional, heterogeneously integrated system;

FIG. 6 illustrates a general block diagram of interfacing the physically compliant, 3-dimensional, heterogeneously integrated system;

FIGS. 7A to 7C illustrate the current consumption characteristic of the physically compliant, 3-dimensional, heterogeneously integrated system in at various stages of fabrication, while the microprocessor is in active mode;

FIGS. 8A and 8B illustrate the current consumption characteristic of the physically compliant, 3-dimensional, heterogeneously integrated system without and with bending;

FIG. 9 illustrates the temperature response of a reference device and the fabricated sensor in physically compliant, 3-dimensional, heterogeneously integrated system;

FIG. 10 illustrates the relative humidity response of the reference device and the fabricated sensor physically compliant, 3-dimensional, heterogeneously integrated system; and

FIG. 11 is flowchart of a method for making the physically compliant, 3-dimensional, heterogeneously integrated system.

### DETAILED DESCRIPTION OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to a system that uses graphene-based temperature and humidity sensors integrated into CMOS electronics platform as an example. However, the embodiments to be discussed next are not limited to graphene-based sensors, or temperature and humidity sensors, or CMOS electronics, or a specific microprocessor/controller or any other component, but may be applied to other type of sensors and/or other type of electronics.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, a physically compliant, standalone CMOS electronic system, integrated in a 3D-coin architecture, using polymers and graphene sensors is formed as a single device platform. In one application, a sequential-etch-back technique is used to transform state-of-the-art CMOS ICs into flexible ICs, and multiple ICs are assembled using a modular Lego approach as discussed in [1]. The other face of the 3D-coin device is configured to host various material (e.g., copper, polymers, and/or graphene) based sensors, which are connected to an interface electronics using through-polymer-via (TPV). The polymeric encapsulation for the electronic interface ensures the biocompatibility as well as is ruggedness.

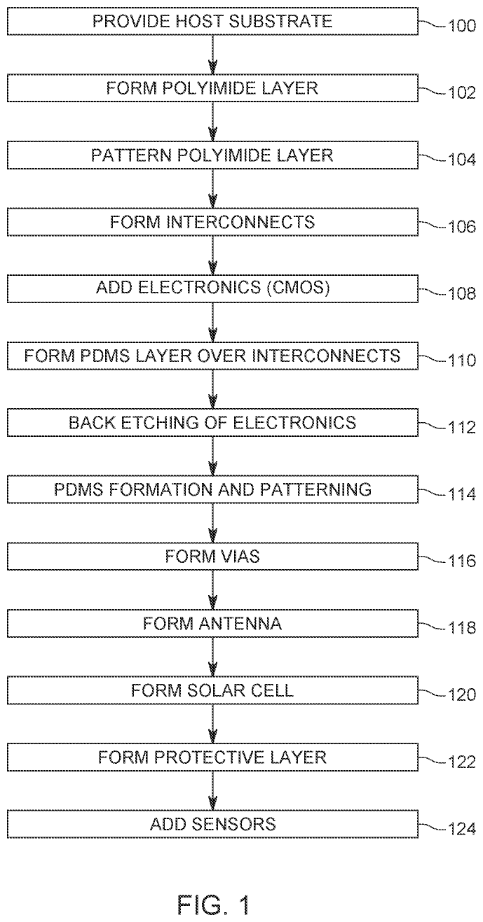

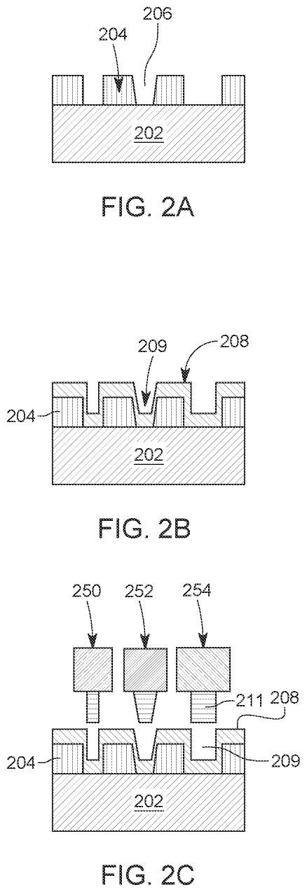

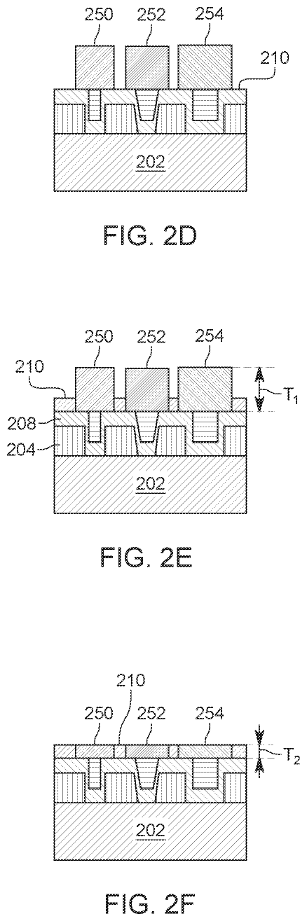

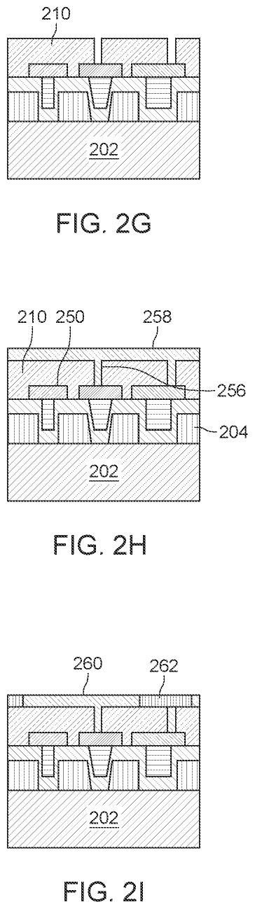

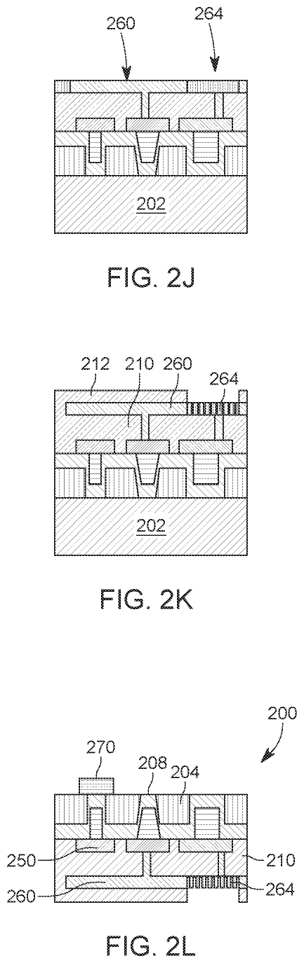

According to a first method, which is presented as a flowchart in FIG. 1, a temporary host substrate 202, for example, bulk silicon (100), is provided in step 100. The temporary host substrate 202 is illustrated in FIG. 2A. In step 102, a polymer layer 204 (e.g., polyimide, also known as PI) is formed, for example, by spinning, over the substrate 202 and then patterned in step 104 to form plural holes 206 that expose the substrate 202. One or more interconnects 208 are made by metal deposition (for example, using Ti/Au 10 nm/100 nm) and lithography in step 106, as shown in FIG. 2B, to form female Lego interfaces. The interconnects 208 have parts that are in direct contact with the substrate 202 and parts that are formed directly on the polyimide layer 204. In step 108, one or more logic/memory elements 250, radio-frequency enabled integrated circuit 252 (i.e., an integrated circuit that includes a transceiver), and one or more batteries 254 are selected after transforming them into male Lego units as described in [1], and transferred to the female interfaces 209, for example, using a soft-vacuum suction based pick-and-place tool for high yield with a placement accuracy of +/−2 μm. Step 108 can be seen as a modular assembly of electronics (CMOS). Note that while this embodiment describes the elements 250 to 254 as being a memory, an integrated circuit, and a battery, any electronics can be used for these elements. Further, the number of elements used in the system can be more or less than three. The same is true for other elements discussed herein, for example, an antenna, or a graphene sensor. These are only examples for illustrating the capability of this method. These elements 250 to 254 are attached similar to Lego pieces (see, for example [1] which describes such a technique) to the interconnects 208, as illustrated in FIG. 2C. Note that each of these elements may have a male conducting part 211 that fits tightly inside a corresponding female interface 209 of the interconnects 208 as shown in FIG. 2D.

The attached electronics is not flexible, i.e., the bare die of ICs assembled on carrier wafer has a thickness that prevents bending of the electronics. After the electronics 250 to 254 is in place, as shown in FIG. 2E, a layer 210 of polydimethylsiloxane (PDMS, for example, 5 μm thick) is formed in step 110 over the interconnects 208 to bond the electronics to the PI interconnects 208 and also to electrically insulate the interconnects from the ambient. Note that the electronics 250 to 254 is selected in such a way that the overall system has data processing and computational capacity (microprocessor/microcontroller), storage capacity (memory), power supply (battery), and communication capabilities (receiver or transmitter or both and an antenna). More or less capabilities may be desired and thus, other electronics or less electronics may be selected for forming the CMOS based standalone system. In one embodiment, it is possible to implement a 280 μm thick MSP430™ microcontroller unit (MCU) (8 kB Flash and 256B RAM from Texas Instruments) as element 252 and solid-state micro lithium ion batteries (Cymbet™ CBC005, thickness=200 μm) as element 254 into corresponding Lego sites 209 using a soft-vacuum suction based pick-and-place tool for high yield (7000 UPH) with a placement accuracy of ±2 μm.

In step 112, the CMOS based electronics is etched back to reduce their thickness from a first value T1 to a second value T2 as illustrated in FIG. 2F. The first thickness value is making the electronics to not be flexible while the second thickness value is making the electronics to become flexible, i.e., the electronics can be bent to have a bending radius of less than 7 mm, or even less than 5 mm, or even to be 2 mm. In this way, the electronics of the system becomes physically compliant, i.e., it can be attached to part of the human body or other elements to follow their natural profile, which most likely is not flat.

In step 114, a layer of PDMS is added on top of the thinned electronics to increase the thickness of the PDMS layer 210 and the layer is patterned in step 116 to form vias (TPV) for future electrical contacts, as illustrated in FIG. 2G. In step 116, electrical connections 256 are formed in the vias by metal deposition and a conducting layer 258 (for example, a copper metal or graphene sheet) is deposited or transferred on top of the PDMS layer 210, as shown in FIG. 2H. Then, in step 118, an antenna 260 is patterned from the conducting layer 258 and one or more openings 262 are formed, as illustrated in FIG. 2I. In step 120, one or more solar cells 264 (or other devices) are placed in the openings 262, directly on the PDMS layer 210, as illustrated in FIG. 2J.

In step 122, a layer of PDMS 212 is formed over the antenna 260, but not over the solar cell 264, as illustrated in FIG. 2K, to protect these elements from the ambient. The solar cell may be corrugated for making it flexible and then can be covered with a layer of PDMS 212. Then, in step 124, the entire system is removed from the host substrate 202, flipped as illustrated in FIG. 2L, and one or more sensors/actuators 270 is electrically and mechanically attached to corresponding interconnects 270. In one embodiment, it is possible to add 1 million or more such sensors into an area of about 25 mm². The sensors 270 are transferred in one embodiment to the polyimide layer 204 as chemical vapor deposited (CVD) grown graphene transferred on PDMS. The sensors 270 may be temperature sensors, humidity sensors, pressure sensors, PH sensors, etc. A method for forming such sensors is disclosed in [2], [3].

The system 200 shown in FIG. 2L includes CMOS electronics, i.e., electronics that include a complementary-metal-oxide-semiconductor structure, only flexible components that are capable to bend to follow any human body shape, and thus, the entire device may have a curvature radius of <5 mm. Note that the system 200 does not include any rigid Si-based substrate, or any other rigid component. The only substrate is the polymer layer 204 and/or the polymer layer 210, where the two polymer layers may be made of different or identical materials. The embodiment illustrated in FIG. 2L shows the first polymer layer 204 being made of PI and the second polymer layer 210 being made of PDMS. In addition, the system 200 is autonomous, i.e., either stores its own energy or can generate its own energy, is capable of electromagnetic communication with an external device for receiving commands and/or transferring the collected data, is so light that it is wearable (i.e., can be attached to the human or animal skin without producing negative effects, especially due to the fact that it is physically compliant and light), and independent of any wire connections.

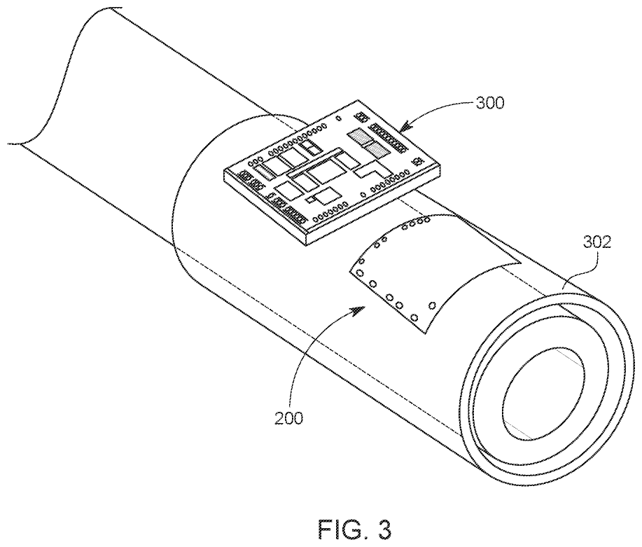

All these features are illustrated in FIG. 3, in which a 10 μm thin system 200 is bent and attached to a solid support 302 having a curvature radius of 3 mm, while, for comparison purposes, a traditional CMOS based device 300 having a typical thickness of 280 μm is shown not being capable to physically conform to the curvature radius of the solid support 302. FIG. 3 illustrates the effectiveness of the process of reducing the rms roughness of the electronics to 5.45 nm while achieving a high-flexibility (e.g., bending radius less than 0.7 mm).

Thus, such a system may be used to monitor plural parameters associated with the human body, contributing not only to the improved health of the population, but also for monitoring ambient conditions that may be detrimental to the health of the wearer.

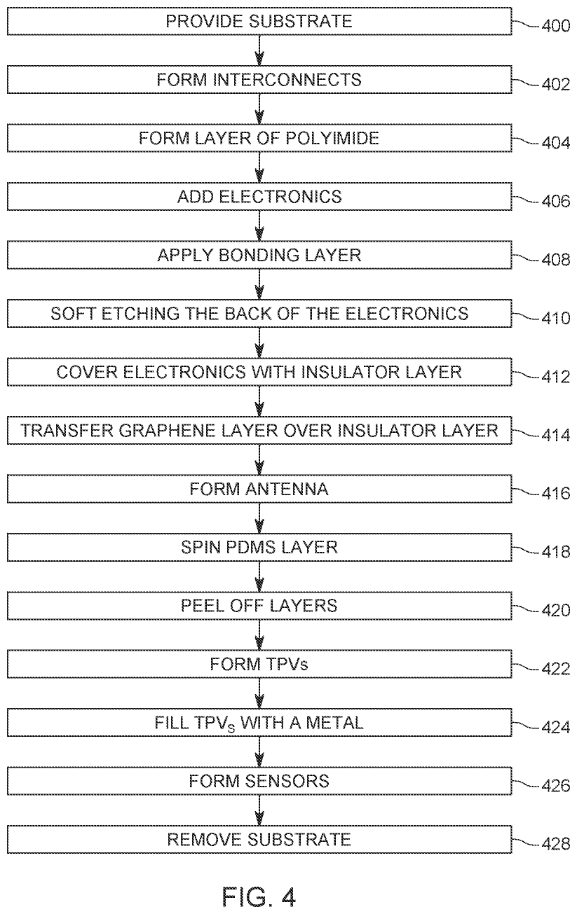

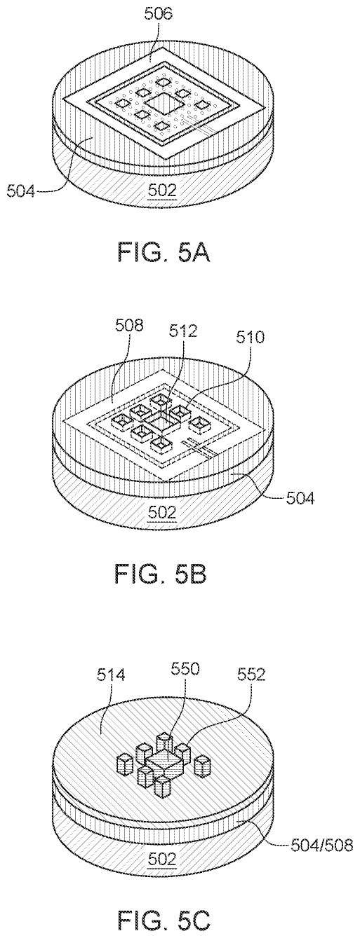

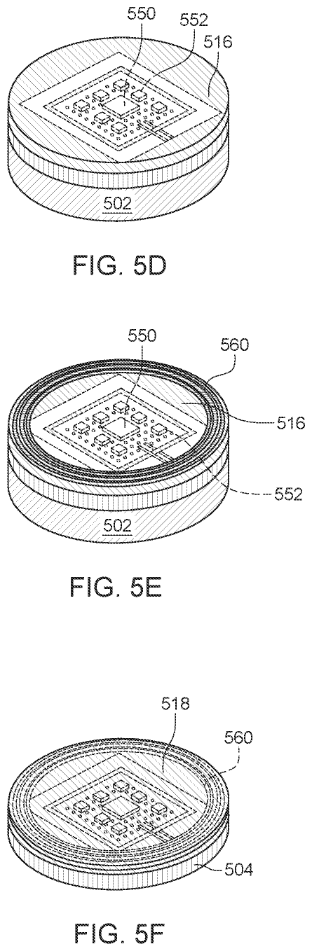

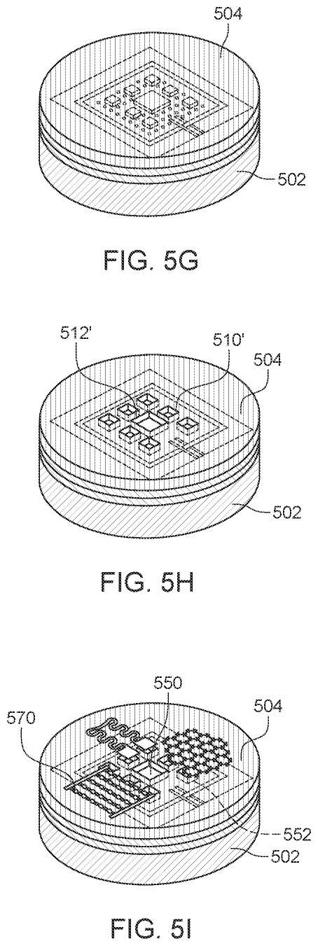

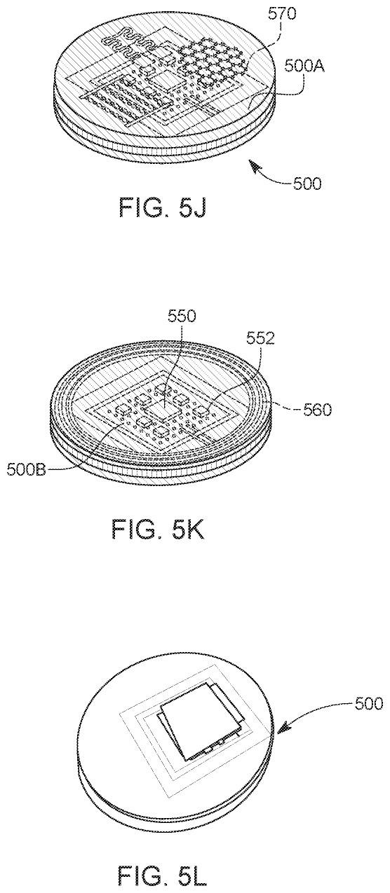

The physically compliant 3D coin hybrid CMOS electronics and graphene sensors system 200 can be manufactured to have 1 million or more sensors by a different method that is now discussed with regard to FIGS. 4 to 5L. The method starts in step 400 by providing a substrate 502 (e.g., a bulk silicon (100) carrier wafer), on which a layer of polyimide 504 has been spun thin (<10 μm) and cured gradually in multi-steps (e.g., 90-300° C.), as shown in FIG. 5A. These layers act as host substrate for modular Lego based lock and key assembly as discussed [1]. In step 402, thin metal Cu (100 nm) interconnects 506 are patterned on the PI layer 504 to form a female Lego site for multiple die assembly, as illustrated in FIG. 5A. In step 404, a second layer 508 of polyimide is formed over the interconnects 506 and Lego style sites trenches 510 and 512 are formed into the second layer 508 of PI by reactive ion etching (RIE), as shown in FIG. 5B. In this embodiment, the first site 510 is for receiving a battery and the second site 512 is for receiving a microcontroller unit. Other types of Lego sites may be formed and their number depends on the needs of the system. In this embodiment, a 280 μm thick MSP430™ MCU 550 and solid-state micro lithium ion batteries 552 (thickness 200 μm) were assembled in step 406 into the Lego sites, as shown in FIG. 5C, by using a soft-vacuum suction based pick-and-place tool for high yield (7000 UPH) with a placement accuracy of ±2 μm. A 5 μm thin layer 514 of polydimethylsiloxane (PDMS) was used in step 408 as a bonding layer between the PI layer 508 and the electronics 550, 552, which was cured at 50° C. for 5 min. Note that any other electronics may be used for the Lego sites, depending on the needs of the final system.

The electronics 550, 552 added in step 406 are typically not flexible, i.e., they cannot be bent. For this reason, a step 410 of sequential-etching of the back silicon material of the electronics is performed, to reduce their thickness until the electronics become bendable, as illustrated in FIG. 5D. This is similar to step 112 discussed above. To protect the lateral electronics shrinkage occurring due to DRIE or other flexing methods, hydrophobic PDMS 516 is spin coated as sidewall spacer in step 412. The PDMS layer 516 also acts as a hard mask for DRIE of Silicon to achieve thin ICs (<10 μm) followed by another thin layer 516 of PDMS, which is added to cover the electronics and protect it from the ambient, as also illustrated in FIG. 5D.

In step 414, chemical vapor deposited (CVD) grown graphene is transferred on the PDMS layer 516 and is then patterned in step 416 using a CO₂ laser (wavelength=10.6 μm) to form a 24 GHz transparent antenna 560, as illustrated in FIG. 5E. In step 420, the formed layers are peeled off from the substrate 502 and this assembly is flipped and transferred on another substrate 502 having cured PDMS, as illustrated in FIG. 5G.

Through-polymer-vias (TPVs) 510′ and 512′ are etched in step 422 through the PI and PDMS layers 504/508 and 514 to make vertical interconnections to the microprocessor 550, battery 552, and antenna 560 as illustrated in FIG. 5H. In one application, the PI and PDMS layers are etched at 60° C. and 10° C. respectively, with varying gaseous mixture of CF₄:O₂ in the ratio of 1:10 and 1:5 respectively in RIE. The TPVs (e.g., 14 μm deep) are filled in step 424 with Cu using electrochemical-deposition (ECD). 15 μm ECD Cu may be grown in the TPVs as illustrated in FIG. 5I, which land on the pads of the MCU 550 and battery 552 dies. Temperature sensors, and/or humidity sensors 570 (for example, a million electrodes array) are patterned in step 426 on the Cu seed layer followed by graphene transfer on the array as the sensing elements. In step 428, the substrate 502 is removed leaving the 1 million sensory array formed on one face 500A of the system 500, as shown in FIG. 5J, and the electronics 550, 552 and the antenna 560 formed on the opposite face 500B of the system, as shown in FIG. 5K. Note that both the sensors and the electronics and antenna are encapsulated into an insulator layer (e.g., 100 μm PDMS) for protection from the ambient, for example, to neutralize possible mechanical stress mismatch from the top and bottom side of the 3D-coin sandwich system 500. Thus, a fully complaint 3D electronic system 500 is obtained, as shown in FIG. 5L, which can be flexed around a 5 mm bending radius, similar to the structure shown in FIG. 3.

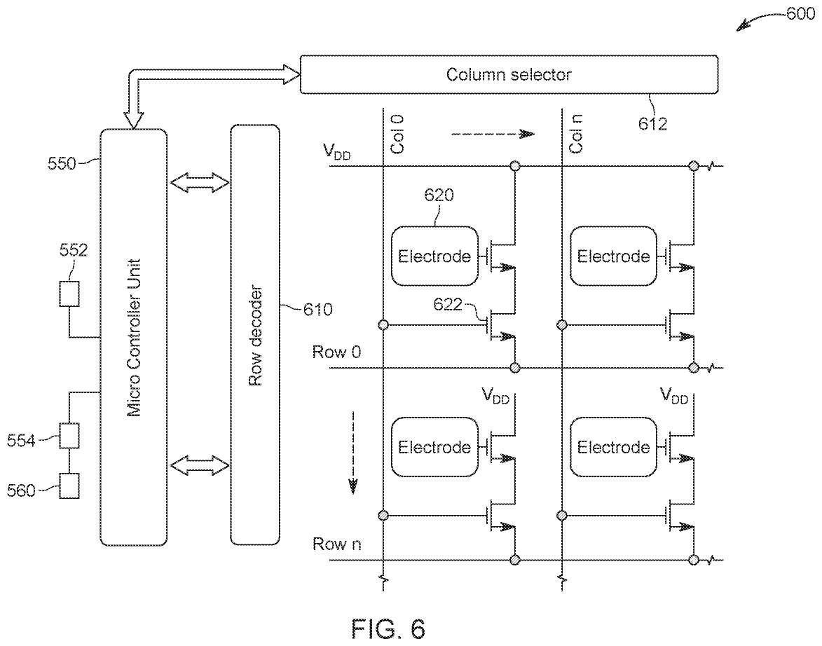

FIG. 6 illustrates a general block diagram of the system 500, adapted for data acquisition from each individual unit cell of the 1 million sensory array 600. The block diagram shows the MCU 550 being connected to a row decoder 610 and a column decoder 612. The row and column decoders 610 and 612 are connected to each electrode 620 of each sensor 570 of the array 600. One or more transistors 622 are used as switches for connecting the MCU 550 to the desired sensor in the array 600. Those skilled in the art will understand that the configuration shown in FIG. 6 is one possible configuration and other known configurations may be used for electrically connecting the electronics 550, 552 to the array of sensors 600 for monitoring any parameter of interest. FIG. 6 also shows the battery 552 being connected to the MCU 550 for supplying power and a transceiver 554 being interposed between the MCU 550 and the antenna 560. The transceiver 554 may be attached to the system 500 in a Lego manner, similar to elements 550 and 552. Those skilled in the art will understand that any other electronic component may be added to the system 500 during the manufacturing process discussed in FIG. 4, as necessary.

To validate the systems 200 and 500, the following electrical tests were performed for the MCU 550 and the sensors 570. The current consumption of the reference microcontroller unit 550 and the processed dies was measured. The variations in the current consumption of the original integrated circuit 550 is recorded during code writing, in the idle state after writing, and during the code run sequence. The same measurements are recorded for the MCU 550 after reducing its thickness to less than 10 μm as illustrated in FIG. 5D, and after making the TPVs for vertical interconnects as illustrated in FIG. 5H.

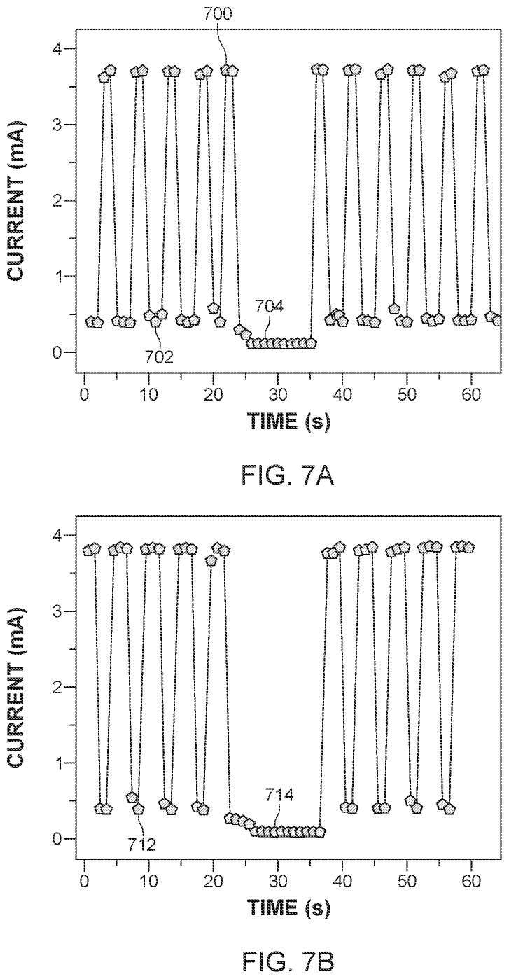

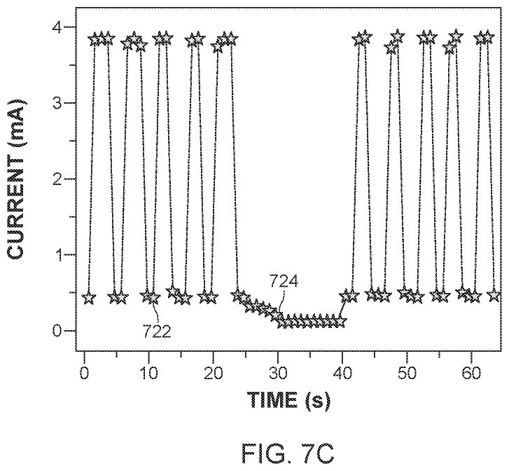

FIG. 7A shows that the average current consumption 700 of a LED programmed to blink is 3.3 mA and the average current consumption 702 of the MCU in the active state is about 0.400 mA for an unprocessed die. The active state average current consumption 712 of the thinned die and the average current consumption 722 after TPV processing did not change significantly and their values are about 0.402 mA and 0.405 mA, respectively, as illustrated in FIGS. 7B and 7A. The currents in the idle state 704, 714, and 724, after coding the sequence, drop to values of 0.108 mA, 0.111 mA and 0.111 mA, respectively. Note that FIG. 7A shows the current values for the traditional die that has a thickness of about 280 μm, FIG. 7B shows the current values for the thin die of about 10 μm (after the step of soft-etching), and FIG. 7C shows the current values after TPV processing of the thin processing unit.

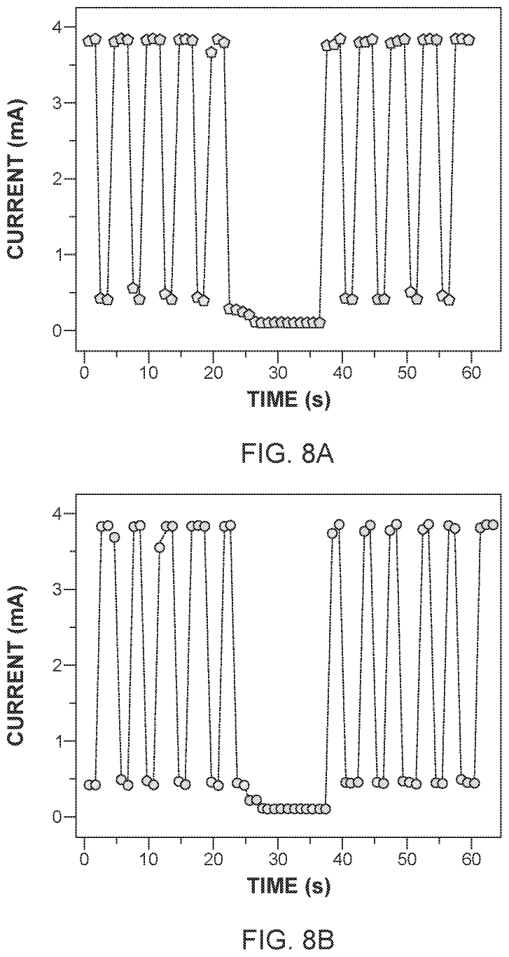

Similarly, the same average current consumptions of the MCU 550 and the integrated LED are presented in FIGS. 8A and 8B to illustrate the mechanically induced variations due to the bending. It can be observed that the current consumption of the thin MCU 550 changes negligibly from −0.402 mA in FIG. 8A, for the unbent state, to ˜0.405 mA in FIG. 8B, for the bent state (bending radius of 5 mm) in active mode. The same values drop to ˜0.111 mA to 0.109 mA in the idle state after writing the code sequence. These values suggest that the systems 200 and 500 are the most pragmatic route for the flexible electronic based IoT and IoE applications.

The implementation of IoT and IoE rely on the integration of different standalone sensory system into a single system. Hence, the systems 200 and 550 discussed above have integrated sensing capabilities that are often required for healthcare applications like temperature and humidity. The systems discussed above were able to integrate 1 million graphene sensors with a 2 μm pitch and a 3 μm electrode in a given area of 25 mm² for humidity sensing. Advanced lithographic techniques can scale these systems further to integrate the same amount of sensors into a 0.25 mm² area, if the sensing electrodes have a size of 100 nm, are spaced at 400 nm, and nanoscale devices are used for multiplexing these sensing electrodes.

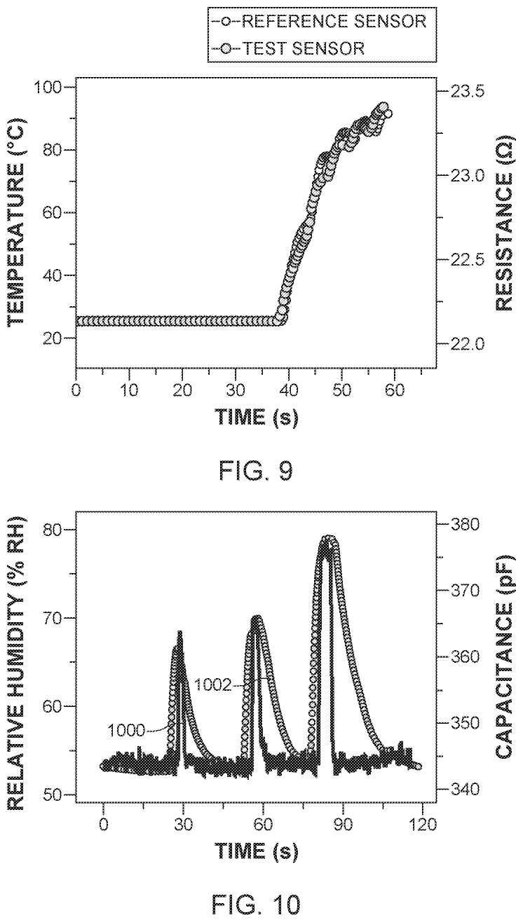

The performance of the fabricated temperature sensors 570 using sputtered copper (200 nm) on the front (top) face of the coin structure 500 is compared with a commercial packaged reference sensor. FIG. 9 shows that the response of both the test and the reference commercial sensors follow the same path when the temperature is increased from room temperature to 90° C. The reference sensor and the novel system were also tested in terms of their sensitivity to humidity. FIG. 10 shows the changes in the capacitance of the sensor due to the application of an external stimulus in the form of human breath at different intervals with a varying humidity level. The response 1000 of the sensor from the system 500 matches the response 1002 of the reference commercial sensor.

An efficient multiplexing technique can be used to acquire the data from the 1 million sensory electrodes corresponding to the sensors of the system 200 or 500. Individual or groups of electrodes can be accessed using multi-level multiplexer architecture with connections using TPV as illustrated in FIG. 6. For communication, in an embodiment, a transparent graphene based Seirpinski fractal antenna may be designed with a bandwidth of 4 GHz and operating frequency of 24 GHz and a solid-state micro-lithium ion battery with the capacity of 5 μAh is also integrated as a power supply.

The embodiments discussed above used a low-temperature, CMOS compatible heterogeneous integration scheme, to manufacture a fully compliant electronic system free from any rigid component, organized in a 3D coin architecture for maximized area efficiency and reduced thermal impact on skin/cells. The embodiments have disclosed reliable processes of making the IC flexible using a sequential-etch-back method (final thickness the electronics is <10 μm, rms roughness of 5.46 nm, and bending radii of up to 700 μm), without any performance degradation. Integration of graphene based 24 GHz antenna, sensors array, and processing unit was achieved for each system 200 and 500.

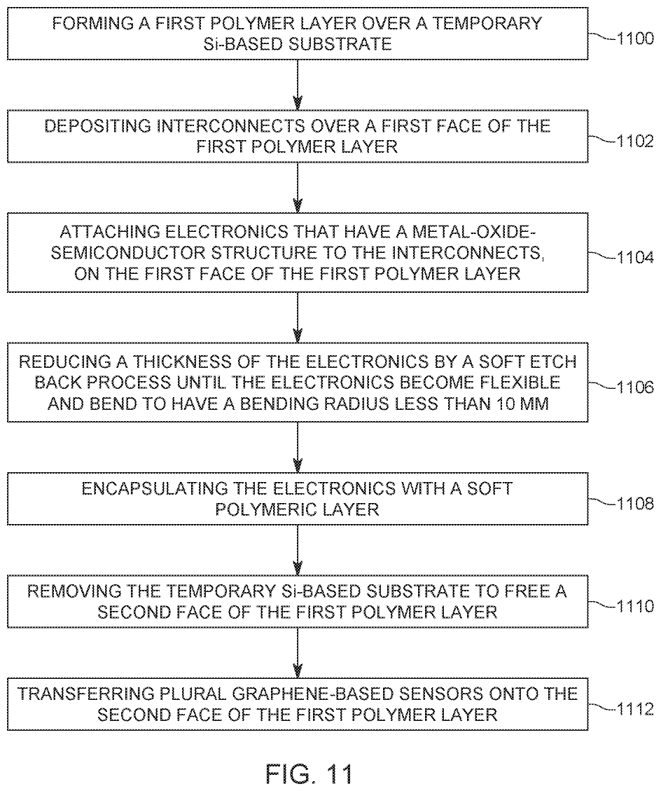

A method for making a physically compliant, 3-dimensional, heterogeneously integrated system 200 is now discussed with regard to FIG. 11. The method includes a step 1100 of forming a first polymer layer 204 over a temporary Si-based substrate 202, a step 1102 of depositing interconnects 208 over a first face of the first polymer layer 204, a step 1104 of attaching electronics 250, 252, 254 that have a metal-oxide-semiconductor structure to the interconnects 208, on the first face of the first polymer layer 204, a step 1106 of reducing a thickness of the electronics 250, 252, 254 by a soft etch back process until the electronics become flexible and bend to have a bending radius less than 10 mm, a step 1108 of soft-polymeric encapsulation 210 cured at 50° C. is performed followed by a step 1110 of removing the temporary Si-based substrate to free a second face of the first polymer layer 204, and a step 1112 of transferring plural graphene-based sensors 270 onto the second face of the first polymer layer 204. The first polymer layer 204 extends between the electronics 250, 252, 254 and the plural graphene-based sensors 270 so that the electronics 250, 252, 254 are prevented from directly contacting the plural graphene-based sensors 270.

In one application, the electronics, the plural graphene-based sensors, the interconnects, and the polymer layer are configured to have a thickness that allow the entire system to bend to have a bending radius less than 10 mm. The method may further include a step of transferring over a million of the plural graphene-based sensors over the second face of the first polymer layer, where the second face of the first polymer layer has an area which is not more than 25 mm². In this application, there is no Si-based substrate when the system is ready.

The method may further include a step of depositing a second layer of polymer over the electronics, and/or a step of transferring a graphene sheet over the second layer of polymer, and/or a step of patterning the graphene sheet to form an antenna. The method may further include a step of patterning the graphene sheet to form an opening, and a step of forming a solar cell in the opening of the graphene sheet, over a same face of the second layer of polymer as the antenna. The method may also include a step of forming slots into the solar cell to become flexible. In one application, the interconnects extend from first face to the second face of the first layer of polymer, and the interconnects are configured to as female sites, to receive the electronics are male components. The electronics includes a processor, a battery, and a transceiver, and the plural graphene-based sensors include temperature and humidity sensors.

A physically compliant, 3-dimensional, heterogeneously integrated system 200 obtained with this method may include electronics 250, 252, 254 that have a metal-oxide-semiconductor structure, plural graphene-based sensors 270, interconnects 208 configured to electrically connect the electronics 250, 252, 254 to the plural graphene-based sensors 270, and a first polymer layer 204 that extends between the electronics 250, 252, 254 and the plural graphene-based sensors 270 so that the electronics 250, 252, 254 are prevented from directly contacting the plural graphene-based sensors 270. The electronics, the plural graphene-based sensors, the interconnects and the polymer layer are configured to have a thickness that allow the entire system to bend to have a bending radius less than 10 mm.

The disclosed embodiments provide a heterogeneous integration of plural graphene sensors in physically compliant 3D coin CMOS electronics for maximized area efficiency and reduced thermal effect. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

[1] S. F. Shaikh, M. T. Ghoneim, R. R. Bahabry, S. M. Khan, and M. M. Hussain, “Modular Lego-Electronics,” Adv. Mater. Technol., vol. 3, no. 2, p. 1700147, February 2018.
[2] S. F. Shaikh et al., “Noninvasive Featherlight Wearable Compliant ‘Marine Skin’: Standalone Multisensory System for Deep-Sea Environmental Monitoring,” Small, vol. 15, no. 10, p. 1804385, March 2019.
[3] J. M. Nassar et al., “Compliant lightweight non-invasive standalone ‘Marine Skin’ tagging system,” npj Flex. Electron., vol. 2, no. 1, p. 13, 2018.

1. A physically compliant, 3-dimensional, heterogeneously integrated system, the system comprising:
electronics that have a metal-oxide-semiconductor structure;
plural graphene-based sensors;
interconnects configured to electrically connect the electronics to the plural graphene-based sensors; and
a first polymer layer that extends between the electronics and the plural graphene-based sensors so that the electronics are prevented from directly contacting the plural graphene-based sensors,
wherein the electronics, the plural graphene-based sensors, the interconnects, and the first polymer layer are configured to have a thickness that allow the entire system to bend to have a bending radius less than 10 mm.

2. The system of claim 1, wherein the plural graphene-based sensors includes over a million sensors and the first polymer layer has an area not more than 25 mm².

3. The system of claim 1, wherein there is no Si-based rigid substrate.

4. The system of claim 1, wherein the electronics is formed on a first face of the first polymer layer and the plural graphene-based sensors are formed on a second face of the first polymer layer, opposite to the first face.

5. The system of claim 4, further comprising:
a second polymer layer formed to encapsulate the electronics.

6. The system of claim 5, further comprising:
a graphene-based antenna formed over the second polymer layer, opposite to the electronics.

7. The system of claim 6, further comprising:
a solar cell formed over a same face of the second polymer layer as the graphene-based antenna.

8. The system of claim 4, wherein the interconnects extend from the first face to the second face of the first polymer layer.

9. The system of claim 1, wherein the electronics includes a processor, a battery, and a transceiver, and the plural graphene-based sensors include temperature and humidity sensors.

10. A method for making a physically compliant, 3-dimensional, heterogeneously integrated system, the method comprising:
forming a first polymer layer over a temporary Si-based substrate;
depositing interconnects over a first face of the first polymer layer;
attaching electronics that have a metal-oxide-semiconductor structure to the interconnects, on the first face of the first polymer layer;
reducing a thickness of the electronics by a soft etch back process until the electronics become flexible and bend to have a bending radius of less than 10 mm;
encapsulating the thinned electronics using a soft polymer;
removing the temporary Si-based substrate to free a second face of the first polymer layer; and
transferring plural graphene-based sensors onto the second face of the first polymer layer,
wherein the first polymer layer extends between the electronics and the plural graphene-based sensors so that the electronics prevented from directly contacting the plural graphene-based sensors.

11. The method of claim 10, wherein the electronics, the plural graphene-based sensors, the interconnects, and the first polymer layer are configured to have a thickness that allow the entire system to bend to have a bending radius of less than 10 mm.

12. The method of claim 10, further comprising:
transferring or fabricating over a million of the plural graphene-based sensors over the second face of the first polymer layer,
wherein the second face of the first polymer layer has an area which is not more than 25 mm².

13. The method of claim 10, wherein there is no Si-based substrate.

14. The method of claim 10, further comprising:
depositing a second polymer layer over the electronics.

15. The method of claim 14, further comprising:
transferring a graphene sheet over the second polymer layer; and
patterning the graphene sheet to form an antenna.

16. The method of claim 15, further comprising:
further patterning the graphene sheet to form an opening; and
forming a solar cell in the opening of the graphene sheet, over a same face of the second polymer layer as the antenna.

17. The method of claim 16, further comprising:
forming slots into the solar cell to become flexible.

18. The method of claim 10, wherein the interconnects extend from the first face to the second face of the first polymer layer, and the interconnects are configured as female sites, to receive the electronics as male parts.

19. The method of claim 10, wherein the electronics includes a processor, a battery, and a transceiver, and the plural graphene-based sensors include temperature and humidity sensors.

20. A physically compliant, 3-dimensional, heterogeneously integrated system the system comprising:
electronics that have a metal-oxide-semiconductor structure;
plural graphene-based sensors;
interconnects configured to electrically connect the electronics to the plural graphene-based sensors; and
a polymer layer that extends between the electronics and the plural graphene-based sensors so that the electronics are prevented from directly contacting the plural graphene-based sensors,
wherein there is no Si-based substrate, and
wherein the plural graphene-based sensors include more than a million graphene sensors.
